(19) United States
(12) Patent Application Publication
(10) Pub. No.: US 2024/0063243 A1
(43) Pub. Date: Feb. 22, 2024

(54) IMAGE SENSOR

(71) Applicant: Samsung Electronics Co., Ltd., Suwon-si (KR)

(72) Inventors: Juyeon IM, Suwon-si (KR); Sungkwan Kim, Suwon-si (KR); Junetaeg Lee, Suwon-si (KR); Doojin Kim, Suwon-si (KR); Minwook Jung, Suwon-si (KR)

(73) Assignee: Samsung Electronics Co., Ltd., Suwon-si (KR)

(21) Appl. No.: 18/300,009

(22) Filed: Apr. 13, 2023

(30) Foreign Application Priority Data
Aug. 19, 2022 (KR) 10-2022-0104084

(51) Int. Cl. H01L 27/146

(52) U.S. Cl. CPC H01L 27/14627; H01L 27/14621; H01L 27/14623; H01L 27/14636

(57) ABSTRACT

An image sensor includes a substrate including a pixel array region and an optical black region surrounding the pixel array region, a micro lens over the pixel array region, a dummy lens over the optical black region, and a blocking bar over the optical black region. A length of the blocking bar is greater than a length of the micro lens and a length of the dummy lens. A top surface of the blocking bar is curved.

### CROSS-REFERENCE TO RELATED APPLICATIONS

This U.S. non-provisional patent application claims priority under 35 U.S.C. § 119 to Korean Patent Application No. 10-2022-0104084, filed on Aug. 19, 2022, in the Korean Intellectual Property Office, the entire contents of which are hereby incorporated by reference.

### BACKGROUND OF THE INVENTION

The present disclosure relates to image sensors, and more particularly, to image sensors including a blocking bar.

An image sensor may be a device for converting an optical image into electrical signals. Image sensors may be categorized as any one of charge coupled device (CCD) image sensors and complementary metal-oxide-semiconductor (CMOS) image sensors. CIS is short for the CMOS image sensor. The CIS may include a plurality of pixels two-dimensionally arranged. Each of the pixels may include a photodiode (PD). The photodiode may convert incident light into an electrical signal.

### SUMMARY

Example embodiments of the inventive concepts may provide an image sensor with improved sensitivity.

In some aspects, an image sensor may include a substrate including a pixel array region and an optical black region surrounding the pixel array region, a micro lens over the pixel array region, a dummy lens over the optical black region, and a blocking bar over the optical black region. A length of the blocking bar may be greater than a length of the micro lens and a length of the dummy lens. A top surface of the blocking bar may be curved.

In some aspects, an image sensor may include a substrate including a pixel array region and an optical black region surrounding the pixel array region, a micro lens over the pixel array region, a dummy lens over the optical black region, and a blocking bar over the optical black region. A length of the blocking bar may be greater than a length of the micro lens and a length of the dummy lens. The blocking bar may surround the micro lens.

In some aspects, an image sensor may include a substrate including a pixel array region and an optical black region surrounding the pixel array region, a color filter over the pixel array region, a black bulk filtering layer over the optical black region, a lens layer on the color filter and the black bulk filtering layer, and a coating layer on the lens layer. The lens layer may include a base portion, a micro lens on the base portion, a dummy lens on the base portion, and a blocking bar on the base portion. A length of the blocking bar may be greater than a length of the micro lens and a length of the dummy lens. The blocking bar may surround the micro lens, and a top surface of the blocking bar may be curved.

### BRIEF DESCRIPTION OF THE DRAWINGS

The above and other aspects, features, and advantages of the present inventive concepts will be more clearly understood from the following detailed description, taken in conjunction with the accompanying drawings, in which:

FIG. 1 is a block diagram illustrating an image sensor according to some example embodiments of the inventive concepts.

FIG. 2 is a circuit diagram illustrating an active pixel sensor array of an image sensor according to some example embodiments of the inventive concepts.

FIG. 3A is a plan view illustrating an image sensor according to some example embodiments of the inventive concepts.

FIG. 3B is an enlarged view of a region ‘A’ of FIG. 3A.

FIG. 3C is a cross-sectional view taken along a line B-B′ of FIG. 3A.

FIG. 3D is a cross-sectional view taken along a line C-C′ of FIG. 3B.

FIG. 3E is a perspective view illustrating a lens layer of the image sensor of FIG. 3A.

FIG. 4A is a plan view illustrating an image sensor according to some example embodiments of the inventive concepts.

FIG. 4B is a cross-sectional view taken along a line D-D′ of FIG. 4A.

FIG. 5 is a plan view illustrating an image sensor according to some example embodiments of the inventive concepts.

FIG. 6 is a plan view illustrating an image sensor according to some example embodiments of the inventive concepts.

FIG. 7 is a cross-sectional view illustrating an image sensor package according to some example embodiments of the inventive concepts.

FIGS. 8A and 8B are cross-sectional views illustrating an image sensor according to some example embodiments of the inventive concepts.

FIG. 9 is a cross-sectional view illustrating an image sensor according to some example embodiments of the inventive concepts.

### DETAILED DESCRIPTION

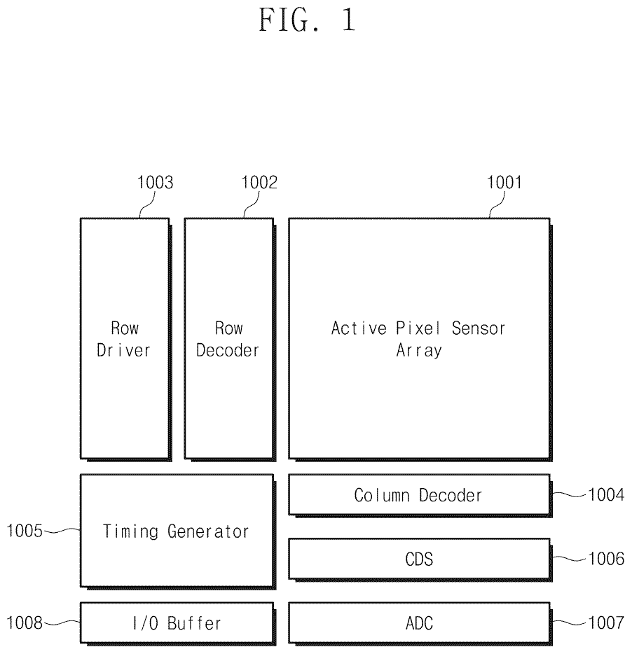

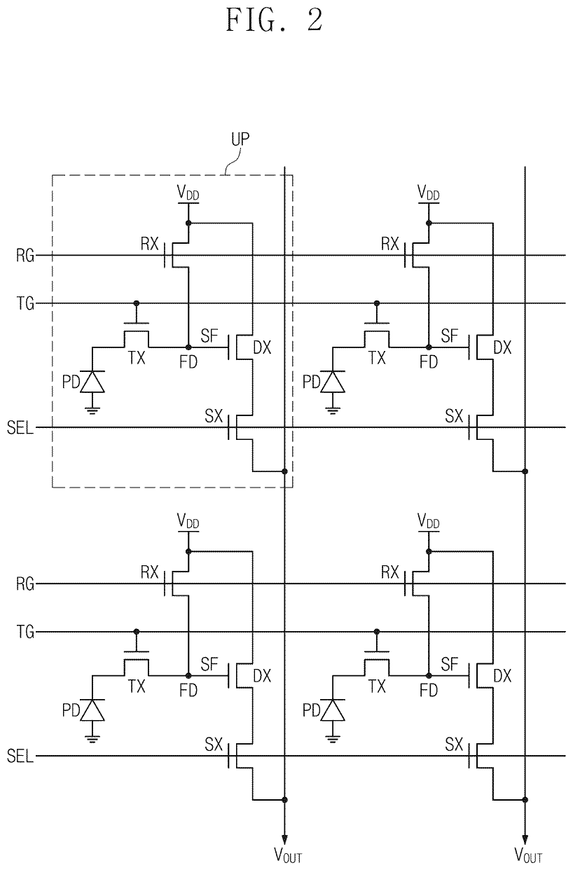

FIG. 1 is a block diagram illustrating an image sensor according to some example embodiments of the inventive concepts. FIG. 2 is a circuit diagram illustrating an active pixel sensor array of an image sensor according to some example embodiments of the inventive concepts.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of unit pixels two-dimensionally arranged and may convert optical signals into electrical signals. The active pixel sensor array 1001 may be driven by a plurality of driving signals (e.g., a pixel selection signal, a reset signal, and a charge transfer signal) provided from the row driver 1003. In addition, the converted electrical signals may be provided to the correlated double sampler 1006.

The row driver 1003 may provide a plurality of driving signals for driving a plurality of the unit pixels to the active pixel sensor array 1001 in response to signals decoded in the row decoder 1002. When the unit pixels are arranged in a matrix form, the driving signals may be provided in the unit of row of the matrix.

The timing generator 1005 may provide timing signals and control signals to the row decoder 1002 and the column decoder 1004.

The correlated double sampler 1006 may receive electrical signals generated from the active pixel sensor array 1001 and may hold and sample the received electrical signals. The correlated double sampler 1006 may doubly sample a specific noise level and a signal level of the electrical signal to output a difference level corresponding to a difference between the noise level and the signal level.

The analog-to-digital converter 1007 may convert an analog signal, which corresponds to the difference level outputted from the correlated double sampler 1006, into a digital signal and may output the digital signal.

The I/O buffer 1008 may latch the digital signals, and the latched signals may be sequentially outputted to an image signal processing unit (not shown) in response to signals decoded in the column decoder 1004.

Referring to FIGS. 1 and 2, the active pixel sensor array 1001 may include a plurality of unit pixels UP, and the unit pixels UP may be arranged in a matrix form. Each of the unit pixels UP may include a transfer transistor TX. Each of the unit pixels UP may further include logic transistors RX, SX and DX. The logic transistors RX, SX and DX may include a reset transistor RX, a selection transistor SX, and a source follower transistor DX. The transfer transistor TX may include a transfer gate TG. Each of the unit pixels UP may further include a photoelectric conversion portion PD and a floating diffusion region FD. The logic transistors RX, SX and DX may be shared by a plurality of the unit pixels UP.

The photoelectric conversion portion PD may generate and accumulate photocharges in proportion to the amount of light incident from the outside. The photoelectric conversion portion PD may include a photodiode, a photo transistor, a photo gate, a pinned photodiode, or a combination thereof. The transfer transistor TX may transfer charges generated in the photoelectric conversion portion PD to the floating diffusion region FD. The floating diffusion region FD may receive the charges generated in the photoelectric conversion portion PD and may cumulatively store the received charges. The source follower transistor DX may be controlled according to the amount of the photocharges accumulated in the floating diffusion region PD.

The reset transistor RX may periodically reset the charges accumulated in the floating diffusion region FD. A drain electrode of the reset transistor RX may be connected to the floating diffusion region PD, and a source electrode of the reset transistor RX may be connected to a power voltage V_{DD}. When the reset transistor RX is turned-on, the power voltage V_{DD} connected to the source electrode of the reset transistor RX may be applied to the floating diffusion region FD. Thus, when the reset transistor RX is turned-on, the charges accumulated in the floating diffusion region FD may be discharged to reset the floating diffusion region FD.

The source follower transistor DX including a source follower gate electrode SF may function as a source follower buffer amplifier. The source follower transistor DX may amplify a potential change in the floating diffusion region FD and may output the amplified potential change to an output line Y_{OUT}.

The selection transistor SX including a selection gate electrode SEL may select the unit pixels UP to be sensed in the unit of row. When the selection transistor SX is turned-on, the power voltage V_{DD} may be applied to a drain electrode of the source follower transistor DX.

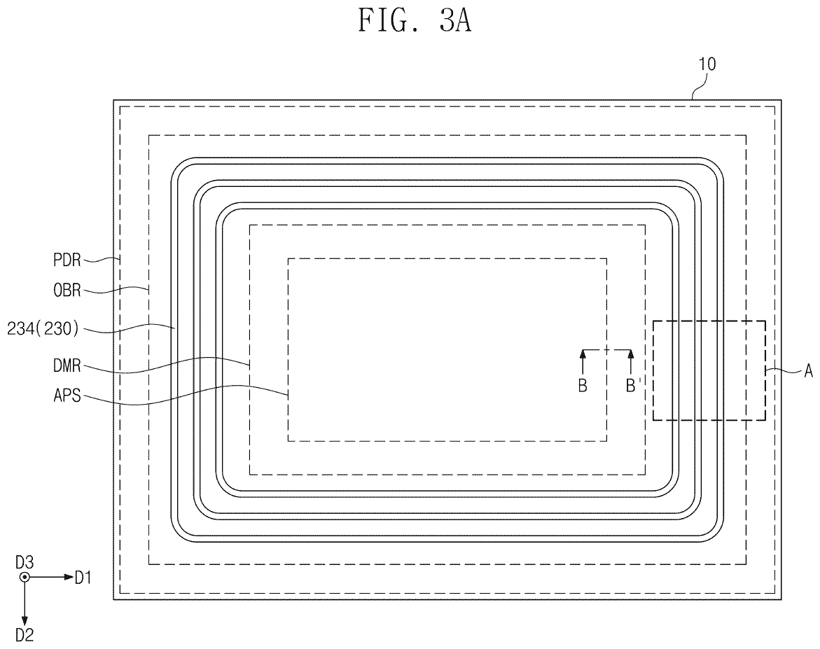

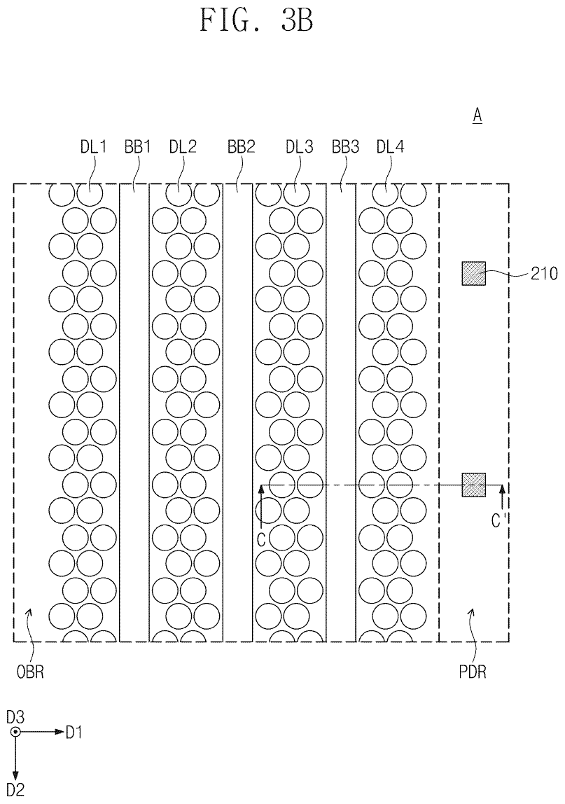

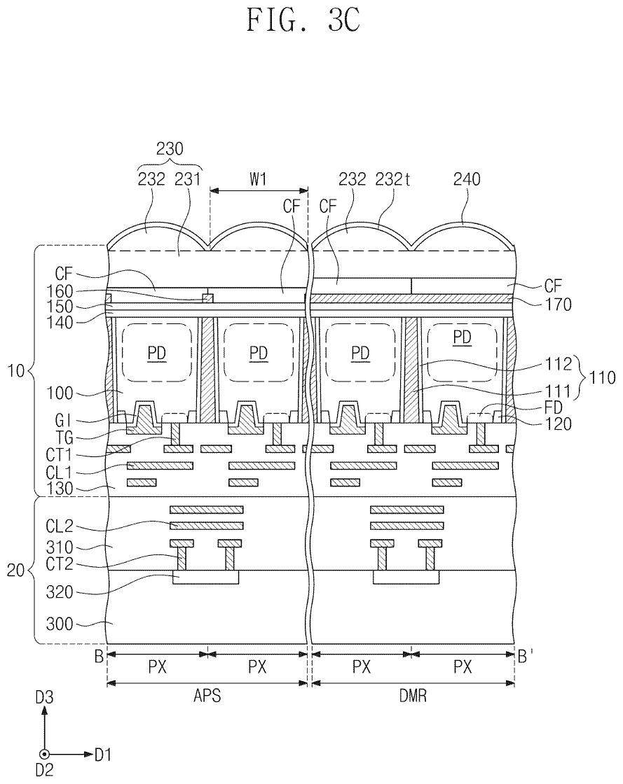

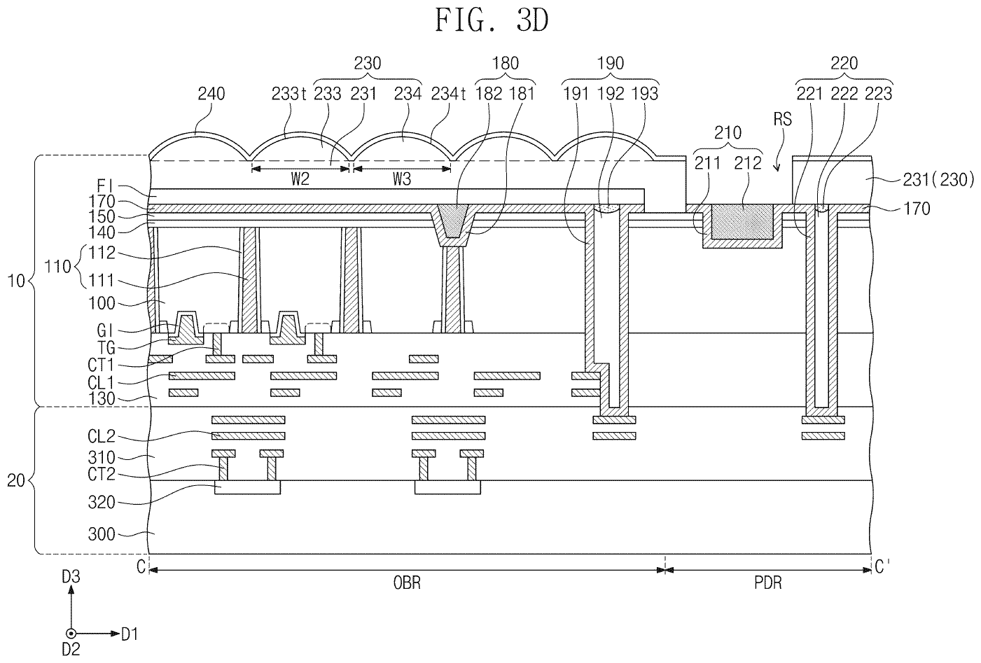

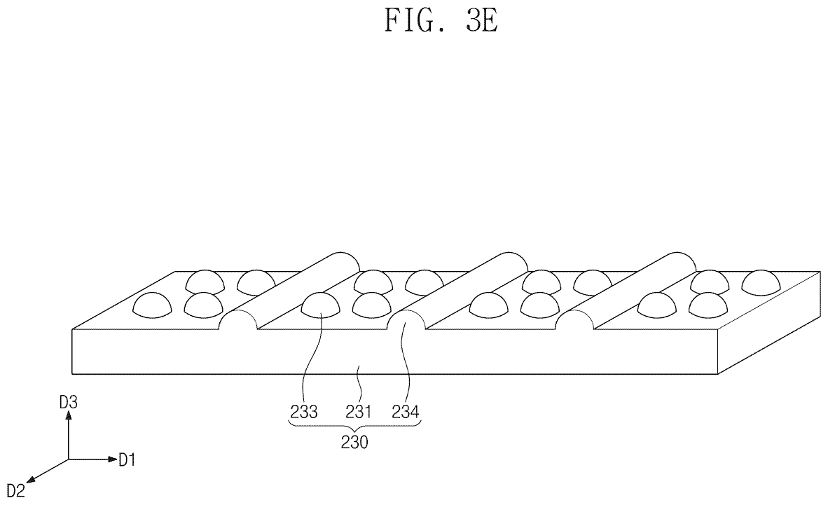

FIG. 3A is a plan view illustrating an image sensor according to some example embodiments of the inventive concepts. FIG. 3B is an enlarged view of a region ‘A’ of FIG. 3A. FIG. 3C is a cross-sectional view taken along a line B-B′ of FIG. 3A. FIG. 3D is a cross-sectional view taken along a line C-C′ of FIG. 3B. FIG. 3E is a perspective view illustrating a lens layer of the image sensor of FIG. 3A.

Referring to FIGS. 3A, 3B, 3C, 3D and 3E, an image sensor may include a sensor chip 10. The sensor chip 10 may include a first substrate 100. The first substrate 100 may have a plate shape extending along a plane defined by a first direction D1 and a second direction D2. The first direction D1 and the second direction D2 may intersect each other. For example, the first direction D1 and the second direction D2 may be horizontal directions perpendicular to each other.

The first substrate 100 may be a semiconductor substrate. For example, the first substrate 100 may be a silicon substrate, a germanium substrate, and/or a silicon-germanium substrate. The first substrate 100 may include dopants having a first conductivity type. For example, the first substrate 100 may include aluminum (Al), boron (B), indium (In) and/or gallium (Ga) as the dopants having the first conductivity type. In some example embodiments, the first substrate 100 may be a silicon-on-insulator (SDI) substrate.

The first substrate 100 may include a pixel array region APS, a dummy region DMR, an optical black region OBR, and a pad region PDR. The pixel array region APS, the dummy region DMR, the optical black region OBR and the pad region PDR may be regions divided when viewed in a plan view defined by the first direction D1 and the second direction D2. The dummy region DMR may surround the pixel array region APS, the optical black region OBR may surround the dummy region DMR and the pixel array region APS, and the pad region PDR may surround the optical black region OBR, the dummy region DMR and the pixel array region APS.

The first substrate 100 may have a front surface and a back surface, which are opposite to each other. Light may be incident to the back surface of the first substrate 100.

The pixel array region APS of the first substrate 100 may include a plurality of pixel regions PX. The pixel region PX of the pixel array region APS may output a photoelectric signal from incident light. The pixel regions PX may be two-dimensionally arranged in the pixel array region APS.

In some example embodiments, the dummy region DMR of the first substrate 100 may include a plurality of pixel regions PX. The pixel regions PX of the dummy region DMR may be dummy pixel regions.

The first substrate 100 may include a plurality of photoelectric conversion regions PD. The photoelectric conversion regions PD may be disposed between the front surface and the back surface of the first substrate 100. The photoelectric conversion regions PD may be provided in the pixel regions PX of the first substrate 100, respectively.

The photoelectric conversion region PD may include dopants having a second conductivity type. The second conductivity type may be different from the first conductivity type. For example, the photoelectric conversion region PD may include phosphorus, arsenic, bismuth and/or antimony as the dopants having the second conductivity type. The photoelectric conversion region PD may be adjacent to the back surface of the first substrate 100.

The first substrate 100 may include a plurality of floating diffusion regions FD. The floating diffusion regions FD may be provided in the pixel regions PX of the first substrate 100, respectively. The floating diffusion regions PD may include dopants having the second conductivity type. The floating diffusion region FD may be adjacent to the front surface of the first substrate 100.

The sensor chip 10 may include a pixel isolation pattern 110. The pixel isolation pattern 110 may be provided in the first substrate 100. The pixel isolation pattern 110 may extend in a third direction D3 to penetrate the first substrate 100. The third direction D3 may intersect the first direction D1 and the second direction D2. For example, the third direction D3 may be a vertical direction perpendicular to the first direction D1 and the second direction D2. The pixel regions PX may be defined by the pixel isolation pattern 110. For example, the pixel isolation pattern 110 may have a grid shape when viewed in a plan view.

The pixel isolation pattern 110 may include an isolation conductive layer 111 and an isolation insulating layer 112. The isolation conductive layer 111 may penetrate the first substrate 100. The isolation insulating layer 112 may be disposed between the isolation conductive layer 111 and the first substrate 100. The isolation conductive layer 111 may include a conductive material. The isolation insulating layer 112 may include an insulating material.

The sensor chip 10 may include a device isolation pattern 120. The device isolation pattern 120 may be provided in the first substrate 100. The device isolation pattern 120 may be disposed adjacent to the front surface of the first substrate 100. The device isolation pattern 120 may define an active region of the first substrate 100. The device isolation pattern 120 may include an insulating material.

The sensor chip 10 may include a first interconnection insulating layer 130 covering the front surface of the first substrate 100. The first interconnection insulating layer 130 may cover the active region of the first substrate 100. The first interconnection insulating layer 130 may include an insulating material. In some example embodiments, the first interconnection insulating layer 130 may be a multi-insulating layer including a plurality of insulating layers.

The sensor chip 10 may include transfer gates TG and gate insulating layers GI. The transfer gate TG may be provided between the first substrate 100 and the first interconnection insulating layer 130. The transfer gate TG may include a conductive material.

The gate insulating layer GI may be provided between the transfer gate TG and the first substrate 100. The gate insulating layer GI may include an insulating material.

First contacts CT1 and first conductive lines CL1 may be provided in the first interconnection insulating layer 130. At least some of the first contacts CT1 may be connected to the floating diffusion regions FD. At least some of the first conductive lines CL1 may be connected to the at least some first contacts CT1. The first contacts CT1 and the first conductive lines CL1 may include a conductive material.

The sensor chip 10 may include a fixed charge layer 140 covering the back surface of the first substrate 100. For example, the fixed charge layer 140 may be a metal oxide layer including insufficient oxygen in terms of a stoichiometric ratio or a metal fluoride layer including insufficient fluorine in terms of a stoichiometric ratio. The fixed charge layer 140 may have negative fixed charges and may accumulate holes. A dark current and a white spot of the first substrate 100 may be effectively reduced by the fixed charge layer 140. In some example embodiments, the fixed charge layer 140 may include a plurality of different layers.

The sensor chip 10 may include an anti-reflection layer 150 on the fixed charge layer 140. For example, the anti-reflection layer 150 may include aluminum oxide. In some example embodiments, the anti-reflection layer 150 may include a plurality of different layers.

The sensor chip 10 may include a fence pattern 160 on the anti-reflection layer 150. The fence pattern 160 may be disposed over the pixel array region APS of the first substrate 100. The fence pattern 160 may divide color filters CF to be described later from each other. For example, the fence pattern 160 may have a grid shape when viewed in a plan view. The fence pattern 160 may include a conductive material. For example, the fence pattern 160 may include tungsten.

The sensor chip 10 may include a light blocking layer 170 on the anti-reflection layer 150. The light blocking layer 170 may be disposed over the dummy region DMR, the optical black region OBR and the pad region PDR of the first substrate 100. The light blocking layer 170 may include a conductive material. The light blocking layer 170 may include the same material as the fence pattern 160. For example, the light blocking layer 170 may include tungsten.

In some example embodiments, the sensor chip 10 may include a protective layer covering the fence pattern 160 and the light blocking layer 170. The protective layer may include an insulating material.

The sensor chip 10 may include a connection contact 180. The connection contact 180 may be disposed over the optical black region OBR of the first substrate 100. The connection contact 180 may penetrate the fixed charge layer 140 and the anti-reflection layer 150 so as to be connected to the pixel isolation pattern 110. The connection contact 180 may include a first contact pattern 181 connected to the pixel isolation pattern 110, and a second contact pattern 182 on the first contact pattern 181.

The first contact pattern 181 may be connected to the light blocking layer 170 without an interface therebetween (e.g., may directly contact). The first contact pattern 181 and the light blocking layer 170 may constitute a single body structure. The first contact pattern 181 may include the same material as the light blocking layer 170. The second contact pattern 182 may include a different material from that of the first contact pattern 181. For example, the second contact pattern 182 may include aluminum.

The sensor chip 10 may include a first connection structure 190. The first connection structure 190 may be disposed over the optical black region OBR of the first substrate 100. The first connection structure 190 may penetrate the fixed charge layer 140, the anti-reflection layer 150, the first substrate 100 and the first interconnection insulating layer 130 so as to be connected to a circuit chip 20 to be described later. The first connection structure 190 may be connected to at least one of the first conductive lines CL1 in the first interconnection insulating layer 130.

The first connection structure 190 may include a first conductive pattern 191 connected to the circuit chip 20, a first insulating pattern 192 on the first conductive pattern 191, and a first capping pattern 193 on the first insulating pattern 192. The first conductive pattern 191 may be connected to the light blocking layer 170 without an interface therebetween (e.g., may directly contact). The first conductive pattern 191 and the light blocking layer 170 may constitute a single body structure. The first conductive pattern 191 may include the same material as the light blocking layer 170.

The first insulating pattern 192 may include an insulating material. The first capping pattern 193 may include an insulating material.

The sensor chip 10 may include a conductive pad 210. The conductive pad 210 may be disposed over the pad region PDR of the first substrate 100. The conductive pad 210 may penetrate the fixed charge layer 140 and the anti-reflection layer 150 so as to be connected to the first substrate 100.

The conductive pad 210 may include a first pad pattern 211 on the first substrate 100 and a second pad pattern 212 on the first pad pattern 211. The first pad pattern 211 may be connected to the light blocking layer 170 without an interface therebetween (e.g., may directly contact). The first pad pattern 211 and the light blocking layer 170 may constitute a single body structure. The first pad pattern 211 may include the same material as the light blocking layer 170.

The second pad pattern 212 may include a different material from that of the first pad pattern 211. For example, the second pad pattern 212 may include aluminum.

The sensor chip 10 may include a second connection structure 220. The second connection structure 220 may be disposed over the pad region PDR of the first substrate 100. The second connection structure 220 may penetrate the fixed charge layer 140, the anti-reflection layer 150, the first substrate 100 and the first interconnection insulating layer 130 so as to be connected to the circuit chip 20 to be described later in detail. The second connection structure 220 may be connected to at least one of the first conductive lines CL1 in the first interconnection insulating layer 130.

The second connection structure 220 may include a second conductive pattern 221 connected to the circuit chip 20, a second insulating pattern 222 on the second conductive pattern 221, and a second capping pattern 223 on the second insulating pattern 222. The second conductive pattern 221 may be connected to the light blocking layer 170 without an interface therebetween (e.g., may directly contact). The second conductive pattern 221 and the light blocking layer 170 may constitute a single body structure. The second conductive pattern 221 may include the same material as the light blocking layer 170.

The second insulating pattern 222 may include an insulating material. The second capping pattern 223 may include an insulating material.

The sensor chip 10 may include the color filters CF. The color filters CF may be disposed over the pixel array region APS and the dummy region DMR of the first substrate 100. The color filters CF may be disposed over the pixel regions PX, respectively. The color filters CF may be provided at positions corresponding to the photoelectric conversion regions PD, respectively. Each of the color filters CF may be a red filter, a blue filter, or a green filter. The color filters CF may constitute a color filter array. For example, the color filters CF may be two-dimensionally arranged in the form of a Bayer pattern. However, other color filters (e.g., a cyan filter, a magenta filter, and/or a yellow filter) and patterns may be used.

The fence pattern 160 may be provided between the color filters CF disposed over the pixel array region APS. The color filters CF disposed over the dummy region DMR may be provided on the light blocking layer 170. In some example embodiments, the color filters CF disposed over the dummy region DMR may be dummy color filters.

The sensor chip 10 may include a black bulk filtering layer FI. The black bulk filtering layer FI may be disposed over the optical black region OBR of the first substrate 100. The black bulk filtering layer FI may be disposed on the light blocking layer 170. The black bulk filtering layer FI may block light having a wavelength different from those of the color filters CF.

The sensor chip 10 may include a lens layer 230. The lens layer 230 may be disposed over the pixel array region APS, the dummy region DMR, the optical black region OBR and the pad region PDR of the first substrate 100. The lens layer 230 may be disposed on the color filters CF and the black bulk filtering layer FI. The lens layer 230 may be transparent. The lens layer 230 may transmit light. The lens layer 230 may include an organic material. For example, the lens layer 230 may include a photoresist material and/or a thermosetting resin.

The lens layer 230 may include a base portion 231 on the color filters CF and the black bulk filtering layer FI. The lens layer 230 may include micro lenses 232, dummy lenses 233 and blocking bars 234 on the base portion 231. The micro lenses 232, the dummy lenses 233 and the blocking bars 234 may be disposed at the same level. The micro lenses 232, the dummy lenses 233 and the blocking bars 234 may be portions protruding from the base portion 231 in the third direction D3. The micro lenses 232, the dummy lenses 233 and the blocking bars 234 may be connected to the base portion 231 without interfaces therebetween. The micro lenses 232, the dummy lenses 233, the blocking bars 234 and the base portion 231 may constitute a single body structure. The micro lenses 232 may be disposed over the pixel array region APS and the dummy region DMR of the first substrate 100. The dummy lenses 233 and the blocking bars 234 may be disposed over the optical black region OBR of the first substrate 100.

The micro lenses 232 may be disposed over the pixel regions PX, respectively. The micro lenses 232 may be provided at positions corresponding to the photoelectric conversion regions PD, respectively. The micro lenses 232 disposed over the dummy region DMR may be dummy micro lenses.

The blocking bar 234 may include two portions extending in the first direction D1 and two portions extending in the second direction D2. The blocking bar 234 may surround the micro lenses 232 when viewed in a plan view. The micro lenses 232 may be disposed between the two portions, extending in the first direction D1, of the blocking bar 234. The micro lenses 232 may be disposed between the two portions, extending in the second direction D2, of the blocking bar 234. The blocking bar 234 may surround at least some of the dummy lenses 233 when viewed in a plan view. In the plan view of FIG. 3A, the blocking bar 234 may have a ring shape.

A length of the blocking bar 234 may be greater than a length of the micro lens 232 and a length of the dummy lens 233. For example, a length, in the first direction D1, of the portion extending in the first direction D1 of the blocking bar 234 may be greater than a length of the micro lens 232 in the first direction D1 and a length of the dummy lens 233 in the first direction D1. The length of the blocking bar 234 may be greater than a length of the pixel array region APS of the first substrate 100. The length may be measured in the direction the blocking bar 234 extends furthest, e.g., either the first direction D1, or the second direction D2, based on the location being considered in the sensor chip 10.

A top surface 232t of the micro lens 232, a top surface 233t of the dummy lens 233 and a top surface 234t of the blocking bar 234 may be curved. A curvature radius of the top surface 232t of the micro lens 232, a curvature radius of the top surface 233t of the dummy lens 233 and a curvature radius of the top surface 234t of the blocking bar 234 may be equal to each other. For example, in the cross-sectional views of FIGS. 3C and 3D, the curvature radius of the top surface 232t of the micro lens 232, the curvature radius of the top surface 233t of the dummy lens 233 and the curvature radius of the top surface 234t of the blocking bar 234 may be equal to each other. In some example embodiments, the curvature radius of the top surface 232t of the micro lens 232, the curvature radius of the top surface 233t of the dummy lens 233 and the curvature radius of the top surface 234t of the blocking bar 234 may be different from each other.

A maximum width of the micro lens 232, a maximum width of the dummy lens 233 and a maximum width of the blocking bar 234 may be equal to each other. For example, a maximum width W1 of the micro lens 232 in the first direction D1, a maximum width W2 of the dummy lens 233 in the first direction D1 and a maximum width W3 of the blocking bar 234 in the first direction D1 may be equal to each other. In some example embodiments, the maximum width of the micro lens 232, the maximum width of the dummy lens 233 and the maximum width of the blocking bar 234 may be different from each other.

An uppermost level of the micro lens 232, an uppermost level of the dummy lens 233 and an uppermost level of the blocking bar 234 may be the same as each other. In some example embodiments, the uppermost level of the micro lens 232, the uppermost level of the dummy lens 233 and the uppermost level of the blocking bar 234 may be different from each other.

The sensor chip 10 may include a coating layer 240 on the lens layer 230. The coating layer 240 may be transparent. The coating layer 240 may conformally cover a top surface of the lens layer 230.

The coating layer 240 may include a first portion on the micro lens 232, a second portion on the dummy lens 233, and a third portion on the blocking bar 234. Top surfaces of the first, second and third portions of the coating layer 240 may be curved.

A recess RS penetrating the coating layer 240 and the lens layer 230 may be defined. The conductive pad 210 may be exposed by the recess RS. The recess RS may be defined by sidewalls of the coating layer 240 and the lens layer 230 and upper surfaces of conductive pad 210.

The image sensor may include the circuit chip 20. The circuit chip 20 may include a second substrate 300. The second substrate 300 may be a semiconductor substrate. In some example embodiments, the second substrate 300 may be a SDI substrate.

The circuit chip 20 may include a second interconnection insulating layer 310 on the second substrate 300. The second interconnection insulating layer 310 may cover an active region of the second substrate 300. The second interconnection insulating layer 310 may include an insulating material. In some example embodiments, the second interconnection insulating layer 310 may be a multi-insulating layer including a plurality of insulating layers.

The circuit chip 20 may include integrated circuits 320 between the second substrate 300 and the second interconnection insulating layer 310. The integrated circuits 320 may include at least one of a logic circuit or a memory circuit.

The circuit chip 20 may include second contacts CT2 and second conductive lines CL2 in the second interconnection insulating layer 310. At least some of the second contacts CT2 may be connected to the integrated circuits 320. At least some of the second conductive lines CL2 may be connected to the at least some second contacts CT2. At least one of the second conductive lines CL2 may be connected to the first connection structure 190. At least one of the second conductive lines CL2 may be connected to the second connection structure 220. The second contacts CT2 and the second conductive lines CL2 may include a conductive material.

Referring to FIGS. 3A and 3B, the dummy lenses 233 may include first dummy lenses DL1, second dummy lenses DL2, third dummy lenses DL3, and fourth dummy lenses DL4. The blocking bars 234 may include a first blocking bar BB1, a second blocking bar BB2, and a third blocking bar BB3.

Unlike FIGS. 3A and 3B, the number of the blocking bars 234 is not limited to 3. In some example embodiments, the number of the blocking bars 234 may be 2 or less or may be 4 or more.

The first blocking bar BB1 may surround the first dummy lenses DL1 and the micro lenses 232 when viewed in a plan view. The second blocking bar BB2 may surround the first blocking bar BB1, the second dummy lenses DL2, the first dummy lenses DL1 and the micro lenses 232 when viewed in a plan view. The third blocking bar BB3 may surround the second blocking bar BB2, the third dummy lenses DL3, the first blocking bar BB1, the second dummy lenses DL2, the first dummy lenses DL1 and the micro lenses 232 when viewed in a plan view.

A distance between the first dummy lens DL1 and the micro lens 232 may be less than a distance between the first blocking bar BB1 and the micro lens 232. The second dummy lens DL2 may be disposed between the first and second blocking bars BB1 and BB2. The third dummy lens DL3 may be disposed between the second and third blocking bars BB2 and BB3. A distance between the fourth dummy lens DL4 and the micro lens 232 may be greater than a distance between the third blocking bar BB3 and the micro lens 232. The first to third blocking bars BB1, BB2 and BB3 may be disposed between the first dummy lens DL1 and the fourth dummy lens DL4.

The first to third blocking bars BB1 to BB3 may have a concentric ring pattern (e.g., the first blocking bar BB1 may be a first, smaller ring, the second blocking bar BB2 may be a larger ring surrounding the first blocking bar BB1, and the third blocking bar BB3 may be the largest ring, surrounding the second blocking bar BB2). In some example embodiments, the first to third blocking bars BB1 to BB3 may have a different shape, and in some example embodiments, the blocking bars BB1 to BB3 may have the same or different types of shapes (e.g., rings, circles, etc.).

A method of manufacturing an image sensor package including the image sensor according to some example embodiments may include applying an adhesive material over the pad region PDR of the first substrate 100 of the image sensor, and forming a dam structure on the adhesive material. For example, the adhesive material may include an epoxy.

Since the blocking bar 234 is provided over the optical black region OBR, it is possible to prevent or reduce the adhesive material applied over the pad region PDR from permeating to the pixel array region APS, and it is possible to prevent or reduce sensitivity of the image sensor from being deteriorated.

Compressive stress may be generated in the blocking bar 234 of the image sensor according to some example embodiments, and the compressive stress of the blocking bar 234 may prevent or reduce the occurrence of a crack of the coating layer 240 occurring over the optical black region OBR from propagating onto the pixel array region APS.

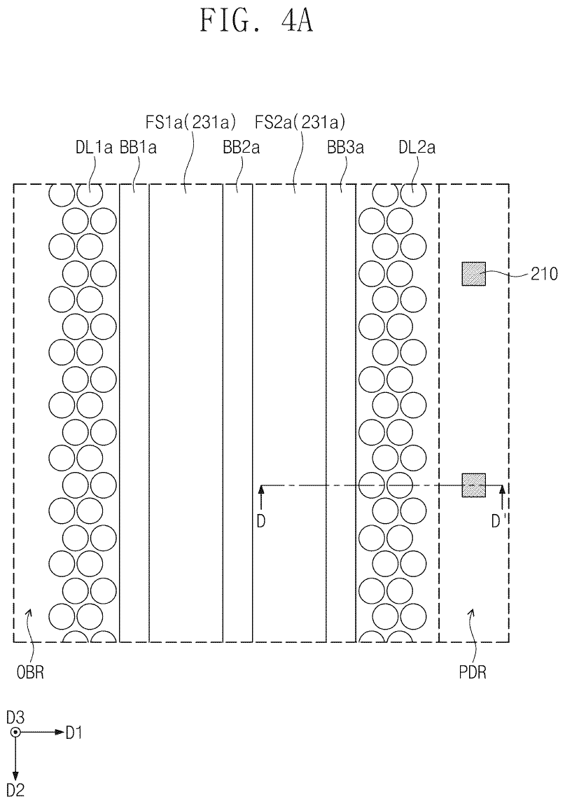

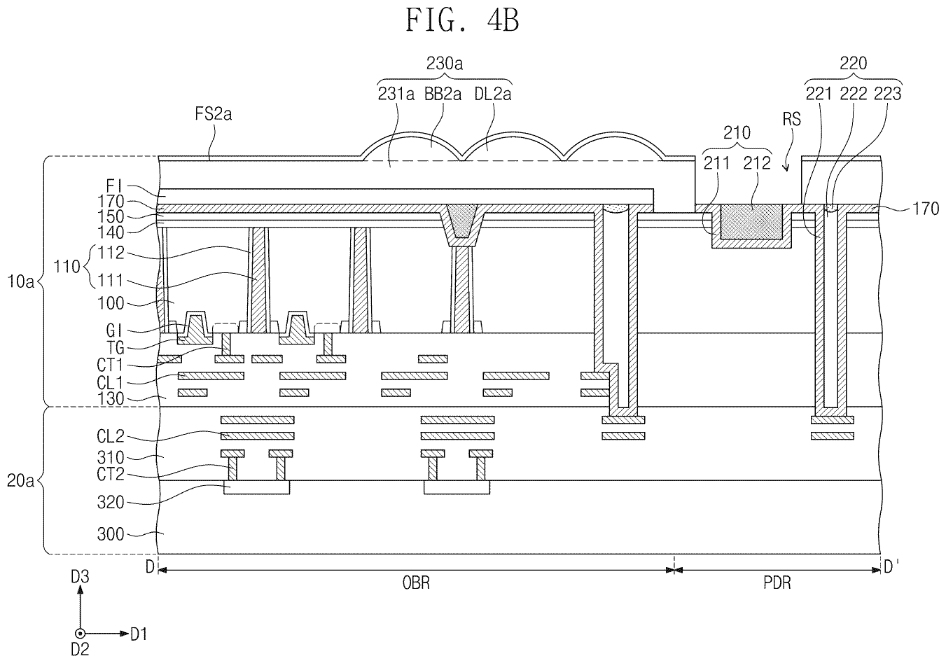

FIG. 4A is a plan view illustrating an image sensor according to some example embodiments of the inventive concepts. FIG. 4B is a cross-sectional view taken along a line D-D′ of FIG. 4A.

Referring to FIGS. 4A and 4B, an image sensor may include a sensor chip 10a and a circuit chip 20a. The sensor chip 10a may include a lens layer 230a.

The lens layer 230a may include a base portion 231a. The lens layer 230a may include first dummy lenses DL1a, second dummy lenses DL2a, a first blocking bar BB1a, a second blocking bar BB2a and a third blocking bar BB3a on the base portion 231a.

The first dummy lenses DL1a may be surrounded by the first to third blocking bars BB1a, BB2a and BB3a when viewed in a plan view. The second dummy lenses DL2a may be closer to the pad region PDR than the third blocking bar BB3a. The dummy lens may not be disposed between the first and second blocking bars BB1a and BB2a. The dummy lens may not be disposed between the second and third blocking bars BB2a and BB3a.

The first to third blocking bars BB1a to BB3a may have a concentric ring pattern (e.g., the first blocking bar BB1a may be a first, smaller ring, the second blocking bar BB2a may be a larger ring surrounding the first blocking bar BB1a, and the third blocking bar BB3a may be the largest ring, surrounding the second blocking bar BB2a). The first to third blocking bars BB1b to BB3b may or may not have a bar at the corner intersections of the first to third blocking bars BB1b to BB3b in the first and second directions D1 and D2.

The base portion 231a may include a first flat top surface FS1a between the first and second blocking bars BB1a and BB2a and a second flat top surface FS2a between the second and third blocking bars BB2a and BB3a.

The first flat top surface FS1a may connect the first blocking bar BB1a and the second blocking bar BB2a. The first flat top surface FS1a may be flat. The first flat top surface FS1a may include two portions extending in the first direction D1 and two portions extending in the second direction D2. The first flat top surface FS1a may have a ring shape when viewed in a plan view. A width of the first flat top surface FS1a may be greater than a width of the first blocking bar BB1a and a width of the second blocking bar BB2a. For example, a width, in the first direction D1, of the portion extending in the second direction D2 of the first flat top surface FS1a may be greater than a width, in the first direction D1, of a portion extending in the second direction D2 of the first blocking bar BB1a and a width, in the first direction D1, of a portion extending in the second direction D2 of the second blocking bar BB2a.

The second flat top surface FS2a may connect the second blocking bar BB2a and the third blocking bar BB3a. The second flat top surface FS2a may be flat. The second flat top surface FS2a may include two portions extending in the first direction D1 and two portions extending in the second direction D2. The second flat top surface FS2a may have a ring shape when viewed in a plan view. A width of the second flat top surface FS2a may be greater than the width of the second blocking bar BB2a and a width of the third blocking bar BB3a. For example, a width, in the first direction D1, of the portion extending in the second direction D2 of the second flat top surface FS2a may be greater than the width, in the first direction D1, of the portion extending in the second direction D2 of the second blocking bar BB2a and a width, in the first direction D1, of a portion extending in the second direction D2 of the third blocking bar BB3a.

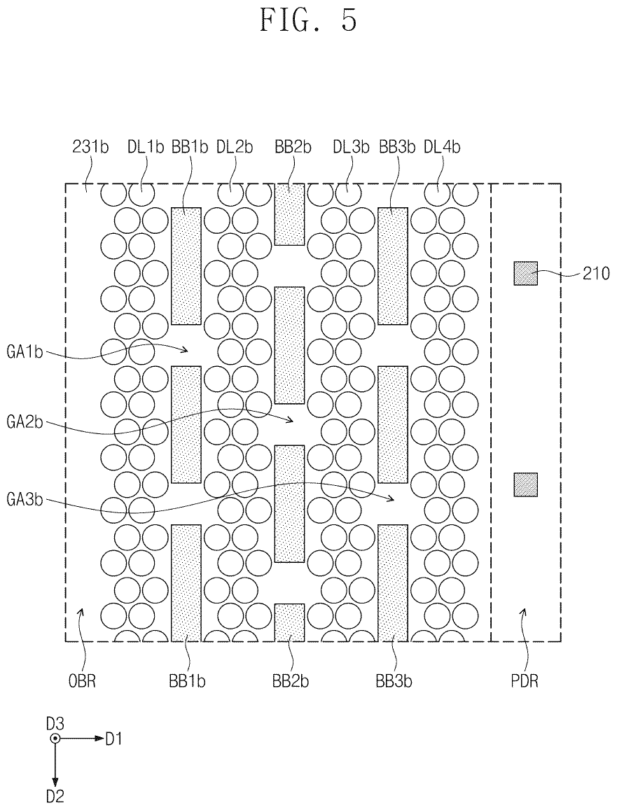

FIG. 5 is a plan view illustrating an image sensor according to some example embodiments of the inventive concepts.

Referring to FIG. 5, an image sensor may include first dummy lenses DL1b, second dummy lenses DL2b, third dummy lenses DL3b, fourth dummy lenses DL4b, first blocking bars BB1b, second blocking bars BB2b, and third blocking bars BB3b.

The first blocking bars BB1b may be spaced apart from each other. The first blocking bars BB1b may include the first blocking bars BB1b extending in the first direction D1 and the first blocking bars BB1b extending in the second direction D2. The first blocking bars BB1b extending in the first direction D1 may be arranged in the first direction D1. The first blocking bars BB1b extending in the second direction D2 may be arranged in the second direction D2.

The second blocking bars BB2b may be spaced apart from each other. The second blocking bars BB2b may include the second blocking bars BB2b extending in the first direction D1 and the second blocking bars BB2b extending in the second direction D2. The second blocking bars BB2b extending in the first direction D1 may be arranged in the first direction D1. The second blocking bars BB2b extending in the second direction D2 may be arranged in the second direction D2.

The third blocking bars BB3b may be spaced apart from each other. The third blocking bars BB3b may include the third blocking bars BB3b extending in the first direction D1 and the third blocking bars BB3b extending in the second direction D2. The third blocking bars BB3b extending in the first direction D1 may be arranged in the first direction D1. The third blocking bars BB3b extending in the second direction D2 may be arranged in the second direction D2.

The first to third blocking bars BB1b to BB3b may have a concentric ring pattern (e.g., the first blocking bars BB1b may be a first, smaller ring, the second blocking bars BB2b may be a larger ring surrounding the first blocking bars BB1b, and the third blocking bars BB3b may be the largest ring, surrounding the second blocking bars BB2b). The first to third blocking bars BB1b to BB3b may or may not have a bar at the corner intersections of the first to third blocking bars BB1b to BB3b in the first and second directions D1 and D2.

A first gap GA1b may be defined between the first blocking bars BB1b adjacent to each other. A second gap GA2b may be defined between the second blocking bars BB2b adjacent to each other. A third gap GA3b may be defined between the third blocking bars BB3b adjacent to each other. Portions of a top surface of the base portion 231b may be exposed by the first to third gaps GA1b, GA2b and GA3b.

A width of the gap GA1b, GA2b or GA3b may be equal to a width of the blocking bar BB1b, BB2b or BB3b. For example, a width, in the first direction D1, of the first gap GA1b provided between the first blocking bars BB1b extending in the second direction D2 may be equal to a width, in the first direction D1, of the first blocking bar BB1b extending in the second direction D2.

A length of the blocking bar BB1b, BB2b or BB3b may be greater than a length of the gap GA1b, GA2b or GA3b. For example, a length, in the second direction D2, of the first blocking bar BB1b extending in the second direction D2 may be greater than a length, in the second direction D2, of the first gap GA1b provided between the first blocking bars BB1b extending in the second direction D2.

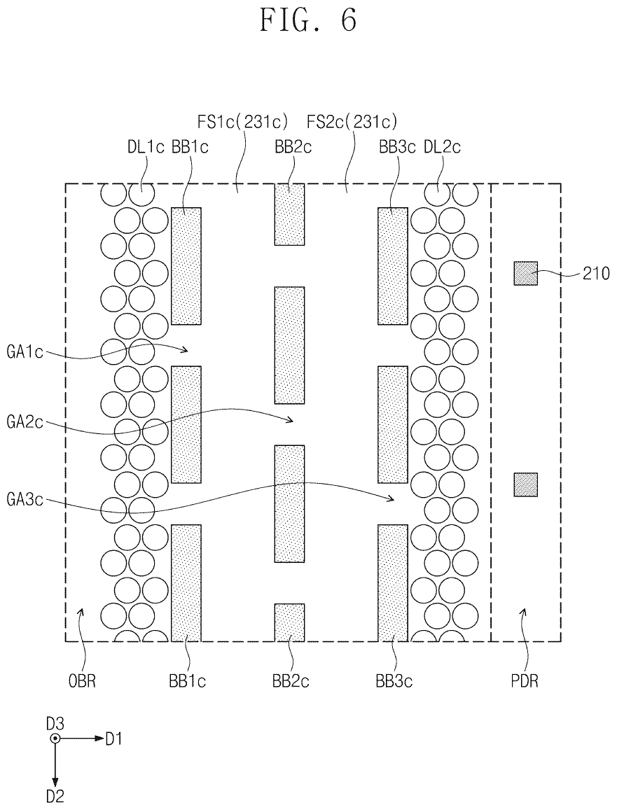

FIG. 6 is a plan view illustrating an image sensor according to some example embodiments of the inventive concepts.

Referring to FIG. 6, an image sensor may include first blocking bars BB1c, second blocking bars BB2c, third blocking bars BB3c, first dummy lenses DL1c surrounded by the first blocking bars BB1c in a plan view, and second dummy lenses DL2c surrounding the third blocking bars BB3c in a plan view.

The first to third blocking bars BB1c to BB3c may have a concentric ring pattern (e.g., the first blocking bars BB1c may be a first, smaller ring, the second blocking bars BB2c may be a larger ring surrounding the first blocking bars BB1c, and the third blocking bars BB3c may be the largest ring, surrounding the second blocking bars BB2c).

First gaps GA1c may be defined between the first blocking bars BB1c, second gaps GA2c may be defined between the second blocking bars BB2c, and third gaps GA3c may be defined between the third blocking bars BB3c.

A base portion 231c may include a first flat top surface FS1c between the first blocking bars BB1c and the second blocking bars BB2c and a second flat top surface FS2c between the second blocking bars BB2c and the third blocking bars BB3c. The first flat top surface FS1c may be connected to the first and second gaps GA1c and GA2c. The second flat top surface FS2c may be connected to the second and third gaps GA2c and GA3c.

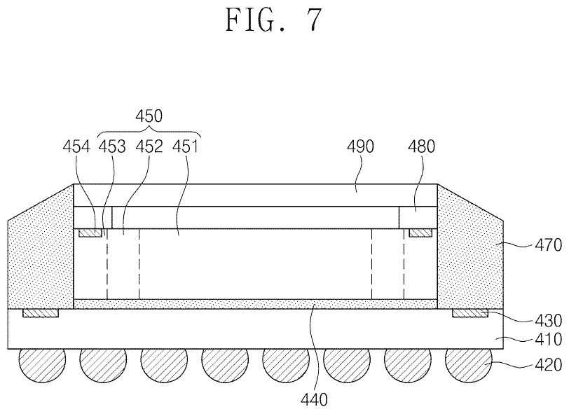

FIG. 7 is a cross-sectional view illustrating an image sensor package according to some example embodiments of the inventive concepts.

Referring to FIG. 7, an image sensor package may include a package substrate 410. For example, the package substrate 410 may be a printed circuit board (PCB).

The package substrate 410 may include upper pads 430. The upper pads 430 may include a conductive material. External connection terminals 420 may be provided under the package substrate 410. The image sensor package may be electrically connected to an external device through the external connection terminals 420. The external connection terminals 420 may include a conductive material.

An adhesive layer 440 may be provided on the package substrate 410. For example, the adhesive layer 440 may include a polymer material.

An image sensor 450 may be provided on the adhesive layer 440. The image sensor 450 may include a pixel array region 451, an optical black region 452, and a pad region 453. The image sensor 450 may include a conductive pad 454 in the pad region 453. For example, the conductive pad 454 may be electrically connected to the upper pad 430 through a wire.

In some example embodiments, the image sensor 450 may include a sensor chip and a circuit chip, and the conductive pad 454 may be provided between the sensor chip and the circuit chip of the image sensor 450 so as to be connected directly to the circuit chip.

A micro lens may be provided in the pixel array region 451 of the image sensor 450. A dummy lens and a blocking bar may be provided in the optical black region 452 of the image sensor 450.

A dam structure 480 may be provided on a portion of the optical black region 452 and the pad region 453 of the image sensor 450. In some example embodiments, the image sensor 450 may be provided on only the pad region 453. The dam structure 480 may be adhered to the image sensor 450 by using an adhesive material (not shown). The pixel array region 451 of the image sensor 450 may be exposed by the dam structure 480. For example, the dam structure 480 may include at least one of a polymer material or a metal. The dam structure 480 may have a ring shape when viewed in a plan view.

A transparent substrate 490 may be provided on the dam structure 480. The transparent substrate 490 may include a material having a high light transmittance. For example, the transparent substrate 490 may include glass.

A molding layer 470 may be provided to surround the transparent substrate 490, the dam structure 480 and the image sensor 450. For example, the molding layer 470 may include a polymer material.

Since the image sensor 450 includes the blocking bar in the image sensor package according to some example embodiments, it is possible to prevent or reduce the adhesive material for adhering the dam structure 480 to the image sensor 450 from permeating to the pixel array region 451, and it is possible to prevent or reduce sensitivity of the image sensor 450 from being deteriorated.

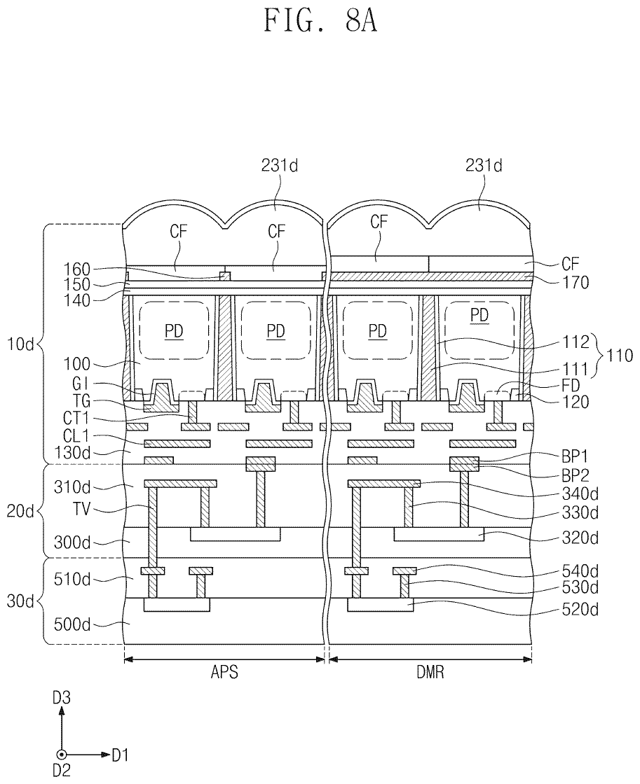

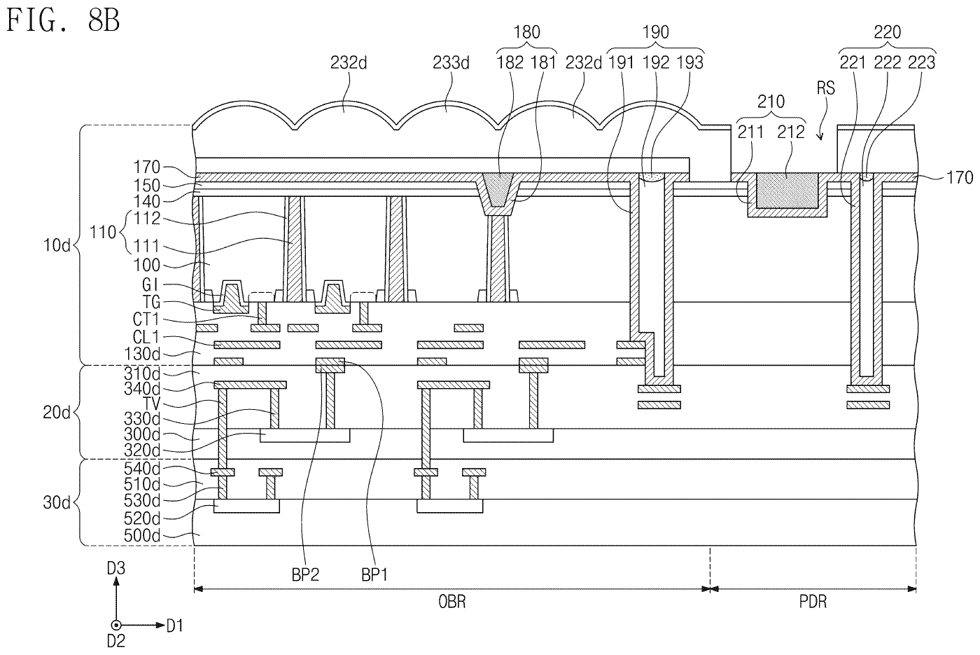

FIGS. 8A and 8B are cross-sectional views illustrating an image sensor according to some example embodiments of the inventive concepts.

Referring to FIGS. 8A and 8B, an image sensor may include a sub-chip 20d, a circuit chip 30d, and a sensor chip 10d. The sub-chip 20d may be provided on the circuit chip 30d, and the sensor chip 10d may be provided on the sub-chip 20d. The sensor chip 10d may include micro lenses 231d, dummy lenses 232d, and a blocking bar 233d.

The sensor chip 10d may include a first substrate 100 and a first interconnection insulating layer 130d. The sub-chip 20d may include a second substrate 300d and a second interconnection insulating layer 310d. The circuit chip 30d may include a third substrate 500d and a third interconnection insulating layer 510d. The first interconnection insulating layer 130d may be in contact with the second interconnection insulating layer 310d. The second substrate 300d may be in contact with the third interconnection insulating layer 510d.

The sensor chip 10d may include a first bonding pad BP1 being in contact with the sub-chip 20d. The sub-chip 20d may include a second bonding pad BP2 being in contact with the first bonding pad BP1. The sensor chip 10d and the sub-chip 20d may be electrically connected to each other through the first and second bonding pads BP1 and BP2. For example, the first and second bonding pads BP1 and BP2 may include copper.

The sub-chip 20d may include an electronic device 320d, first contacts 330d connected to the electronic device 320d, and a first conductive line 340d. The first contact 330d may be connected to the first conductive line 340d or the second bonding pad BP2. The electronic device 320d may include at least one of a selection transistor, a reset gate, or a source follower gate. The first contact 330d and the first conductive line 340d may be provided in the second interconnection insulating layer 310d.

The circuit chip 30d may include an integrated circuit 520d, a second contact 530d connected to the integrated circuit 520d, and a second conductive line 540d connected to the second contact 530d. The second contact 530d and the second conductive line 540d may be provided in the third interconnection insulating layer 510d.

A through-via TV may be provided. The through-via TV may penetrate the second substrate 300d of the sub-chip 20d. The through-via TV may be connected to the first conductive line 340d and the second conductive line 540d. The sub-chip 20d and the circuit chip 30d may be electrically connected to each other through the through-via TV. The through-via TV may include a conductive material.

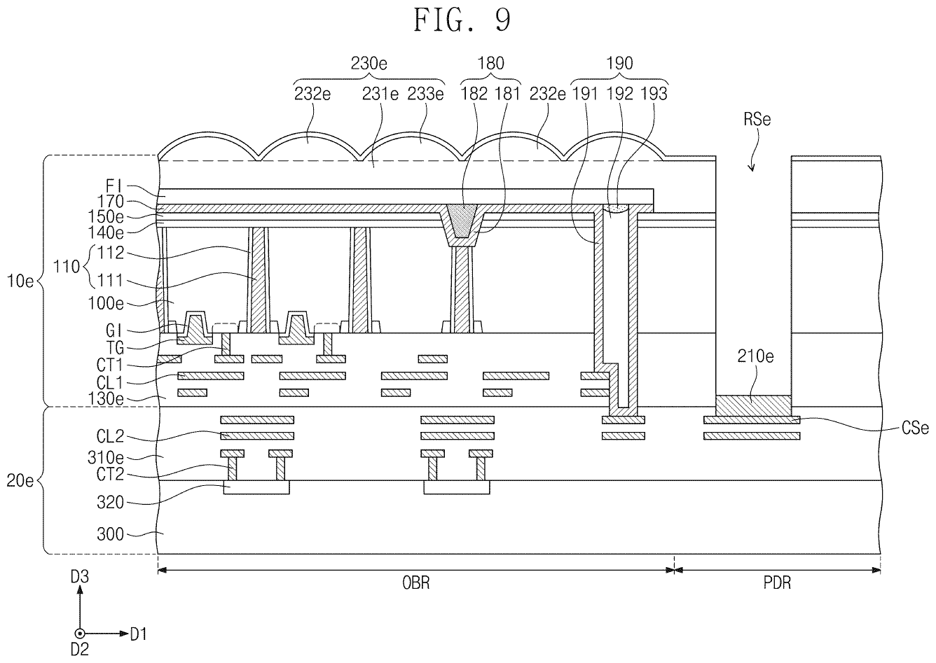

FIG. 9 is a cross-sectional view illustrating an image sensor according to some example embodiments of the inventive concepts.

Referring to FIG. 9, an image sensor may include a sensor chip 10e and a circuit chip 20e. The sensor chip 10e may include a base portion 231e, dummy lenses 232e, and a blocking bar 233e.

The image sensor may include a conductive pad 210e connected directly to the circuit chip 20e. The conductive pad 210e may be provided in a recess RSe. The recess RSe may penetrate a lens layer 230e, an anti-reflection layer 150e, a fixed charge layer 140e, a first substrate 100e and a first interconnection insulating layer 130e of the sensor chip 10e to expose a conductive structure CSe in a second interconnection insulating layer 310e of the circuit chip 20e. The conductive pad 210e may be connected directly to the conductive structure CSe in the second interconnection insulating layer 310e of the circuit chip 20e. The conductive pad 210e may include a conductive material.

The conductive structure CSe may include a conductive material. The conductive structure CSe may be a conductive line, a conductive contact, or a conductive pad.

The image sensor of FIG. 1 (or other circuitry, for example, the active pixel sensor array 1001, the row decoder 1002, the row driver 1003, the column decoder 1004, the timing generator 1005, the correlated double sampler (CDS) 1006, the analog-to-digital converter (ADC) 1007, and the input/output (I/O) buffer 1008) may include hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

When the terms “about,” “substantially,” or “same” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The image sensor according to some example embodiments of the inventive concepts may include the blocking bar on the optical black region, thereby preventing or reducing the adhesive material applied on the optical black region from permeating to the pixel array region and preventing or reducing the sensitivity of the image sensor from being deteriorated.

While some example embodiments of the inventive concepts have been particularly shown and described, it will be understood by one of ordinary skill in the art that variations in form and detail may be made therein without departing from the spirit and scope of the attached claims.

What is claimed is:

1. An image sensor comprising:
a substrate including a pixel array region and an optical black region surrounding the pixel array region;
a micro lens over the pixel array region;
a dummy lens over the optical black region; and
a blocking bar over the optical black region,
a length of the blocking bar being greater than a length of the micro lens and a length of the dummy lens, and
a top surface of the blocking bar being curved.

2. The image sensor of claim 1, wherein the blocking bar surrounds the micro lens.

3. The image sensor of claim 2, wherein the blocking bar includes:
a first blocking bar surrounding the micro lens; and
a second blocking bar surrounding the first blocking bar.

4. The image sensor of claim 3, wherein the dummy lens includes:
first dummy lenses surrounded by the first blocking bar; and
second dummy lenses disposed between the first and second blocking bars.

5. The image sensor of claim 1, wherein a curvature radius of the top surface of the blocking bar is equal to a curvature radius of a top surface of the micro lens.

6. The image sensor of claim 1, wherein a width of the blocking bar is equal to a width of the micro lens.

7. The image sensor of claim 1, wherein
the blocking bar includes a plurality of blocking bars extending in a first direction, and
the blocking bars are arranged in the first direction.

8. The image sensor of claim 1, wherein
the blocking bar includes:
first blocking bars; and
second blocking bars farther from the micro lens than the first blocking bars,
the first blocking bars are arranged in a first direction, and
the second blocking bars are arranged in the first direction.

9. The image sensor of claim 8, wherein
gaps are defined between the first blocking bars, and
a length of each of the first blocking bars is greater than a length of each of the gaps.

10. The image sensor of claim 1, wherein an uppermost level of the blocking bar is the same as an uppermost level of the micro lens.

11. An image sensor comprising:
a substrate including a pixel array region and an optical black region surrounding the pixel array region;
a micro lens over the pixel array region;
a dummy lens over the optical black region; and
a blocking bar over the optical black region,
a length of the blocking bar being greater than a length of the micro lens and a length of the dummy lens, and
the blocking bar surrounding the micro lens.

12. The image sensor of claim 11, further comprising:
a base portion connected to the micro lens, the dummy lens, and the blocking bar.

13. The image sensor of claim 12, wherein
the blocking bar includes:
a first blocking bar; and
a second blocking bar surrounding the first blocking bar, and
the base portion includes a flat top surface connecting the first blocking bar and the second blocking bar.

14. The image sensor of claim 11, wherein
the blocking bar includes blocking bars extending in a first direction,
the blocking bars are arranged in the first direction, and
a gap is between the blocking bars.

15. The image sensor of claim 11, further comprising:
a coating layer covering the micro lens, the dummy lens, and the blocking bar.

16. The image sensor of claim 11, wherein a top surface of the blocking bar is curved.

17. The image sensor of claim 11, wherein a width of the blocking bar is equal to a width of the micro lens.

18. The image sensor of claim 11, wherein a width of the blocking bar is different from a width of the micro lens.

19. An image sensor comprising:
a substrate including a pixel array region and an optical black region surrounding the pixel array region;
a color filter over the pixel array region;
a black bulk filtering layer over the optical black region;
a lens layer on the color filter and the black bulk filtering layer; and
a coating layer on the lens layer,
the lens layer including:
a base portion;
a micro lens on the base portion;
a dummy lens on the base portion; and
a blocking bar on the base portion,
a length of the blocking bar being greater than a length of the micro lens and a length of the dummy lens,
the blocking bar surrounding the micro lens, and
a top surface of the blocking bar being curved.

20. The image sensor of claim 19, wherein
the coating layer includes:
a first portion on the micro lens;
a second portion on the dummy lens; and
a third portion on the blocking bar, and
a top surface of the third portion of the coating layer is curved.
